(19) United States
(12) Patent Application Publication
(10) Pub. No.: US 2011/0141705 A1
(43) Pub. Date: Jun. 16, 2011

(54) PRINTED WIRING BOARD AND ELECTRONIC APPARATUS

(75) Inventors: Masakazu TAKESUE, Kawasaki (JP); Keiichi YAMAMOTO, Kawasaki (JP)

(73) Assignee: FUJITSU LIMITED, Kawasaki-shi (JP)

(21) Appl. No.: 12/961,650

(22) Filed: Dec. 7, 2010

(30) Foreign Application Priority Data
Dec. 10, 2009 (JP) 2009-280822

(51) Int. Cl. H05K 5/00; H05K 1/11

(52) U.S. Cl. 361/752; 174/261

(57) ABSTRACT

A printed wiring board supports an electronic component thereon. The printed wiring board includes an opening which is recessed from a surface of the printed wiring board. The opening has a dimension which houses the electronic component therein. A plurality of pads is disposed on a bottom surface of the opening. The plurality of pads has a skew arrangement in a grid pattern with respect to inner edges of the opening.

### CROSS-REFERENCE TO RELATED APPLICATION

This application is based upon and claims the benefit of priority of Japanese Patent Application No. 2009-280822, filed on Dec. 10, 2009, the entire contents of which are incorporated herein by reference.

### FIELD

Embodiments discussed herein are related to a printed wiring board, and an electronic apparatus.

### BACKGROUND

As methods for fabricating a printed wiring board unit by mounting electronic components represented by large scale integration (LSI) on a printed wiring board, a flip chip method (for example, JP-A-8-222840) and a ball grid array (BGA) technique (for example, JP-A-9-162527) are known. In these techniques, electronic components are arranged in a state in which semi-sphere shaped or sphere shaped solder bumps are sandwiched between the electronic components and electrode pads on a printed wiring board, and then the solder bumps are melted to mount the electronic components on the printed wiring board.

However, when deformation occurs in the printed wiring board on which the electronic components are soldered due to an external force or thermal expansion, there is a concern that the electronic components are detached when stress of the deformation concentrates on soldered portions. Therefore, for an electronic apparatus in which the printed wiring board unit where the electronic components are soldered is installed, a design robust enough to suppress deformation of the printed wiring board unit is required. Such a robust design can make it difficult to reduce size and weight of the electronic apparatus.

### SUMMARY

According to an embodiment of the invention, a printed wiring board for mounting an electronic component thereon is provided. The printed wiring board includes an opening which is recessed from a surface of the printed wiring board. The opening has a dimension which houses the electronic component therein. A plurality of pads is disposed on a bottom surface of the opening. The plurality of pads has a skew arrangement in a grid pattern with respect to inner edges of the opening.

It is to be understood that both the foregoing general description and the following detailed description are exemplary and explanatory, and are not restrictive of the invention.

### BRIEF DESCRIPTION OF DRAWINGS

FIG. 1 illustrates a personal computer corresponding to an example of an electronic apparatus of the present invention.

FIG. 2 illustrates an internal structure of a main body of the personal computer in FIG. 1.

FIGS. 3A and 3B schematically illustrate a mounting position of an electronic component on a wiring board according to a first embodiment.

FIG. 4 illustrates shapes and arrangement of electrode pads according to the first embodiment.

FIGS. 5A and 5B illustrate an electronic component placed on the electrode pads according to the first embodiment.

FIG. 6 illustrates a positional relationship between the electrode pads and solder bumps according to the first embodiment.

FIG. 7 illustrates a state after solder wets and moves.

FIGS. 8A and 8B illustrate a self-alignment of the electronic component according to the first embodiment.

FIG. 9 illustrates that stresses on solder joints are alleviated.

FIGS. 10A and 10B illustrate an electronic component according to a second embodiment.

FIGS. 11A and 11B illustrate a state in which the electronic component according to the second embodiment is placed in an opening of a wiring board.

FIGS. 12A and 12B illustrate a self-alignment of the electronic component according to the second embodiment.

FIGS. 13A and 13B illustrate an electronic component according to a third embodiment.

FIG. 14 illustrates a placement example of the electronic component according to the third embodiment.

FIG. 15 illustrates a modified example of placement of the electronic component according to the third embodiment.

FIG. 16 illustrates a self-alignment of the electronic component according to the third embodiment.

FIGS. 17A and 17B illustrate an opening according to a fourth embodiment.

FIGS. 18A and 18B illustrate a state in which an electronic component is placed in the opening according to the fourth embodiment.

FIGS. 19A and 19B illustrate a self-alignment of the electronic component according to the fourth embodiment.

FIGS. 20A and 20B illustrate a wall according to a fifth embodiment.

FIG. 21 illustrates a state in which an electronic component is placed inside the wall according to the fifth embodiment.

FIGS. 22A and 22B illustrate a self-alignment of the electronic component according to the fifth embodiment.

FIG. 23 illustrates that stresses on solder joints are alleviated according to the fifth embodiment.

### DESCRIPTION OF EMBODIMENTS

Hereinafter, embodiments the present invention of a printed wiring board, a printed wiring board unit, and an electronic apparatus will be described with reference to the drawings.

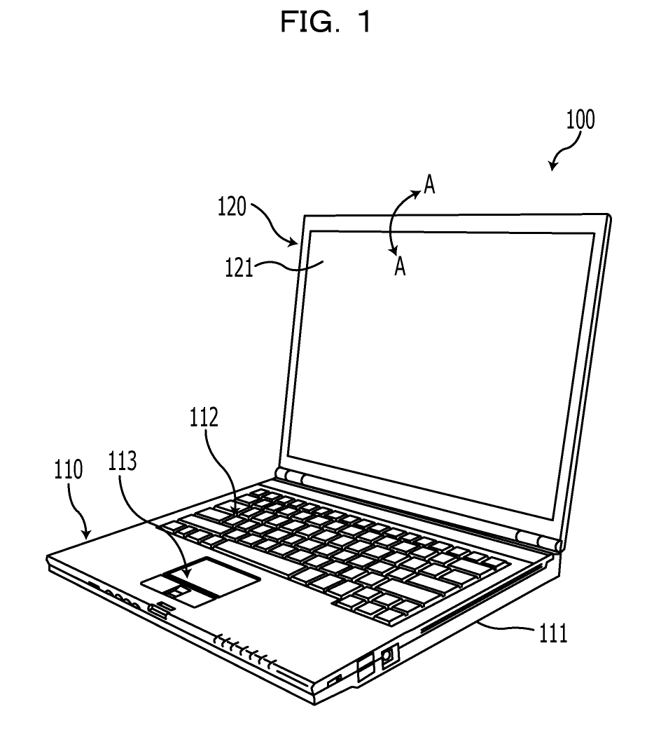

FIG. 1 illustrates a personal computer corresponding to an example of the electronic apparatus of the present invention.

The personal computer 100 for mobile use shown in FIG. 1 can include a main body 110 and a display portion 120 openable and closable relative to the main body 100 with a hinge. A display panel 121 is fitted into the inside portion of the display portion 120 which faces the main body when the display portion 120 is closed. The main body 110 has a structure in which a keyboard 112 and a touchpad 113 are mounted in an enclosure 111.

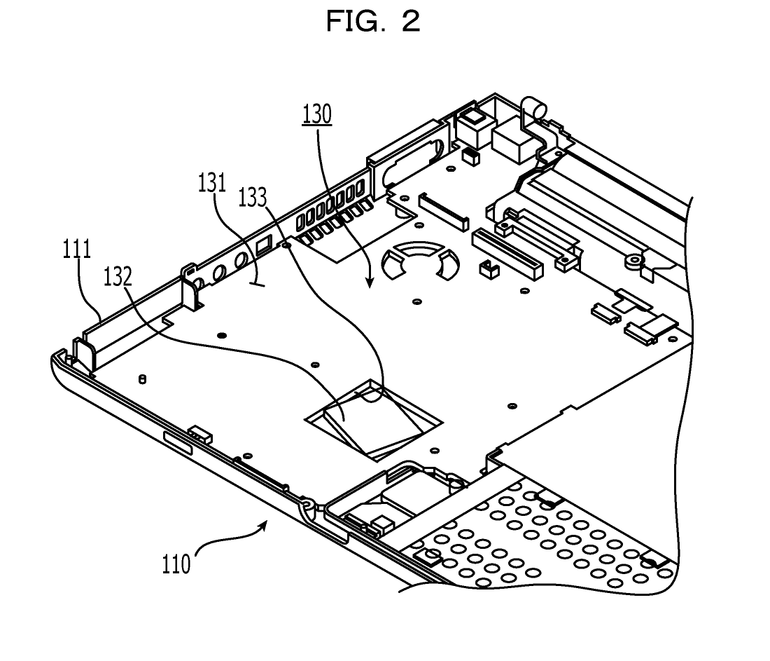

FIG. 2 illustrates an example of an internal structure of the main body of the personal computer in FIG. 1.

As shown in FIG. 2, a printed circuit board unit 130 is mounted in the enclosure 111 of the main body 110. Although the printed circuit board unit 130 is a unit in which various electronic components are mounted on the printed wiring board 131, for convenience of description, electronic components, wiring, and the like other than one electronic component 132 are omitted from the figures.

The wiring board 131 has an opening 133 recessed from the surface of the wiring board 131. The opening 133 surrounds the bottom area recessed from the surface of the wiring board 131. The electronic component 132, having a package form of a rectangular plate shape, is mounted in the area surrounded by the opening 133. Each of the four corners of the electronic component 132 comes into contact with the opening 133, so that the electronic component 133 pushes the opening 133 in the direction to expand the opening 133.

In this embodiment, the opening 133 is recessed from the surface, so that the electronic component 132 is buried in the wiring board 131. This contributes to thinning of the circuit board 130, the main body 110, and the personal computer 100.

Hereinafter, an example of a structure of the circuit board 130 around the electronic component 132 will be described in detail, and in addition, a mounting method of the electronic component 132 will be described.

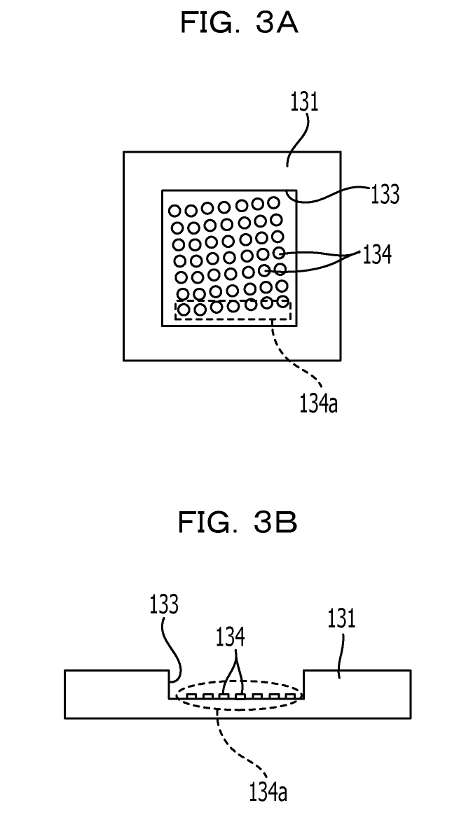

FIG. 3 schematically illustrates a mounting position of the electronic component on the wiring board according to the first embodiment.

In FIG. 3, only a portion near the opening 133 of the wiring board 131 is shown. FIG. 3A illustrates a top view. On the other hand, FIG. 3B illustrates a side perspective view.

As described above, the opening 133 is provided in the wiring board 131. Electrode pads 134 are arranged in an area inside the opening 133. In the arrangement of the electrode pads 134, a row of electrode pads 134a located at the most front row in the top view of FIG. 3A are shown in the side perspective view of FIG. 3B. The arrangement of the electrode pads 134 is a rectangular arrangement as a whole, and the area surrounded by the opening 133 is also rectangular in shape. However, the orientation of the rectangle of the arrangement is tilted from the orientation of the rectangle of the area. The tilt angle of the arrangement of the electrode pads 134 is preferred to be about 1 to 10 degrees.

Here, the arrangement and structure of the electrode pads 134 will be described in further detail.

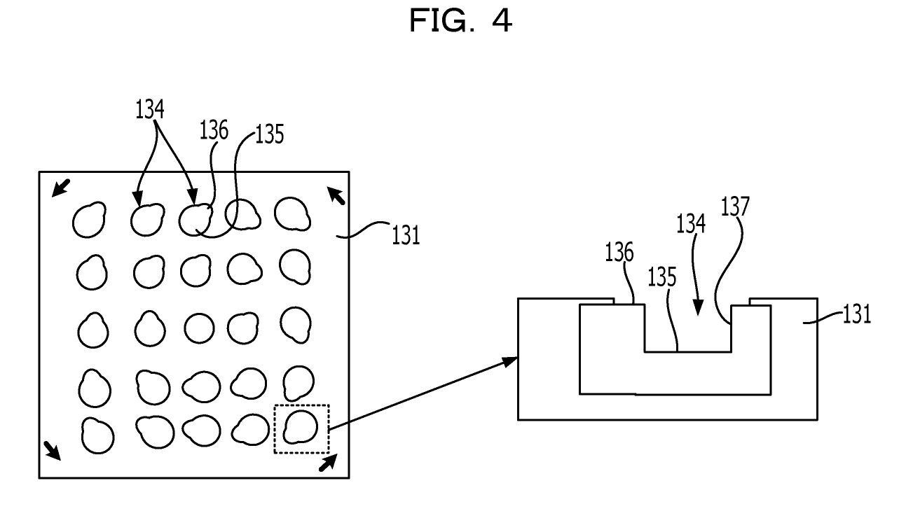

FIG. 4 illustrates shapes and arrangement of electrode pads according to the first embodiment.

Although FIG. 4 illustrates the area in which the electrode pads 134 are arranged in the wiring board 131, FIG. 4 illustrates a concept of the arrangement of the electrode pads 134, so that the number of the electrode pads 134 shown in FIG. 4 is different from that shown in FIG. 3. On the right side of FIG. 4, an enlarged view of a cross-sectional structure focused on a single electrode pad 134 is shown.

The electrode pad 134 includes a circular-shaped pad main body 135 and a protruding portion 136 having a size smaller than the pad main body 135 and protruding to the outside of the circular-shape of the pad main body 135. As a result, the planar shape of the electrode pad 134 is deviated with respect to the center of the electrode pad 134. In the center of the pad main body 135, a circular-shaped depression 137 recessed into the wiring board 131 is formed by a drill. The depression 137 is located at a deviated position with respect to the center of the electrode pad 134.

The orientations of the deviation of the shape of each electrode pad 134 are shown by rotation directions indicated by arrows in FIG. 4. The orientation of the protruding portion 136 is opposite to the rotation direction. As a result, when seeing the arrangement of the electrodes 134 as a whole, the orientations of the deviations of the shapes and the orientations of the protruding portions 136 are spirally directed. In other words, the orientations of the deviations of the shapes and the orientations of the protruding portions 136 form a spiral-shaped trajectory with respect to a pad at the center of the arrangement.

Further, the position of the depression 137 in each electrode pad 134 is deviated in the rotation direction indicated by the arrow with respect to the center of the electrode pad 134. As a result, when seeing the arrangement of the electrodes 134 as a whole, the orientations of the deviations of the depressions 137 with respect to the center of the electrode pad 134 are also spirally directed.

Such plurality of electrode pads 134 correspond to an example of a plurality of pads arranged in a grid pattern according to the above-described embodiment.

When mounting the electronic component 132 described above, the electronic component 132 is mounted on the electrode pads 134 arranged in the manner described above.

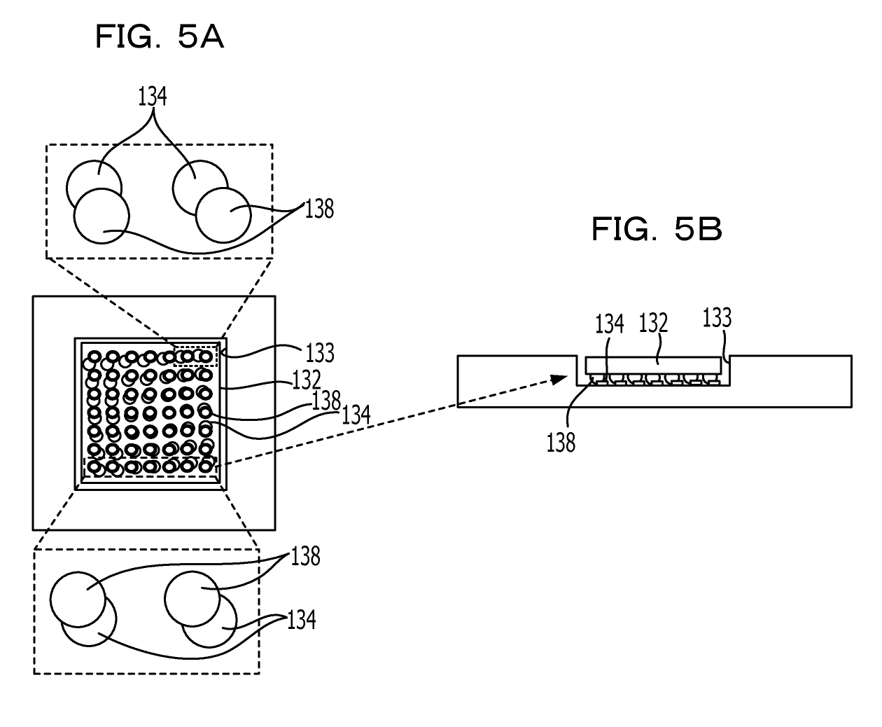

FIG. 5 illustrates the electronic component placed on the electrode pads according to the first embodiment.

In FIG. 5, to easily understand a positional relationship between the electronic component 132 and the electrode pads 134 or the like, a state is illustrated in which the portion hidden under the electronic component 132 is seen through the electronic component 132. FIG. 5A illustrates a top view of the electronic component 132 and partially enlarged views of the electrode pads 134, and FIG. 5B illustrates a side perspective view of the electronic component 132 and the electrode pads 134.

The electronic component 132 is placed on the electrode pads 134 so that the rectangular outer shape of the electronic component 132 is aligned almost squarely with the rectangular area surrounded by the opening 133. Ball-shaped solder bumps 138, each of which has a role of a connecting pin between the electronic component 132 and the electrode pad 134, are attached on the bottom surface of the electronic component 132 (on the surface facing the electrode pads 134). Specifically, the ball grid array (BGA) technique is employed here. The orientation of the arrangement of the solder bumps 138 is also aligned with the rectangular outer shape of the electronic component 132.

On the other hand, as described above, the orientation of the arrangement of the electrode pads 134 is tilted or shifted from the rectangle of the area. As a result, the positions of the electrode pads 134 are shifted from the positions of the solder bumps 138. The partially enlarged view shown above the top view of FIG. 5A illustrates that, in the upper right portion of the arrangement of the electrode pads 134, the solder bumps 138 are shifted from the electrode pads 134 in the lower right direction. Also, the partially enlarged view shown below the top view of FIG. 5A illustrates that, in the lower left portion of the arrangement of the electrode pads 134, the solder bumps 138 are shifted from the electrode pads 134 in the upper left direction.

The positional relationship between the electrode pads 134 and the solder bumps 138 will be described in further detail.

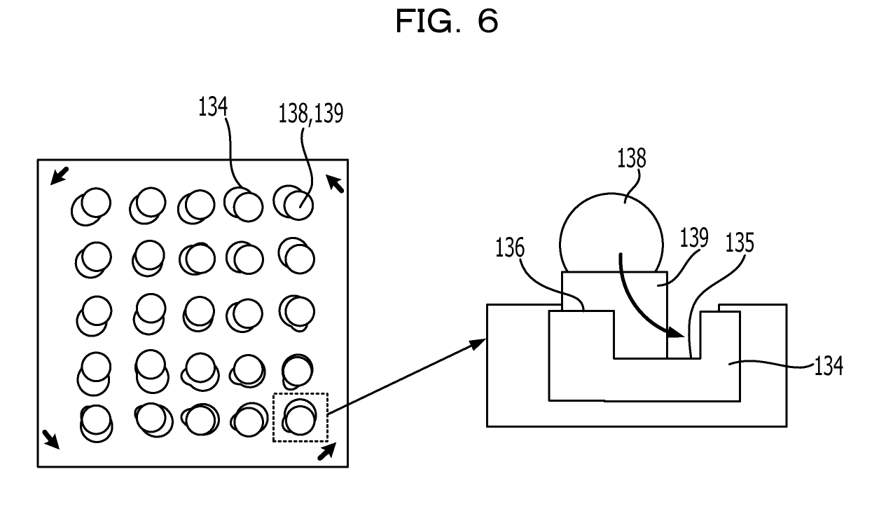

FIG. 6 illustrates an example of the positional relationship between the electrode pads and solder bumps according to the first embodiment.

In the same manner as FIG. 4, FIG. 6 illustrates the area where the above-described electrode pads 134 are arranged on the wiring board 131. On the right side of FIG. 6, an enlarged view of a cross-sectional structure focused on a single electrode pad 134 is shown.

Although omitted in the above description, more specifically, when the solder bump 138 is placed on the electrode pad 134, solder printing 139 is performed on the electrode pad 134 and the solder bump 138 is placed on the solder printing 139.

As described above, the position of the solder bump 138 is shifted from the center of the electrode pad 134, and the solder printing 139 is also printed in a position shifted in the same manner. More specifically, the shifted position is a position shifted toward the protruding portion 136 of the electrode pad 134.

After the electronic component 132 is placed on the electrode pads 134 in such a positional relationship, the solder bumps 138 and the solder printing 139 are heated along with the wiring board 131, so that the solder bumps 138 and the solder printing 139 melt. When the solder bumps 138 and the solder printing 139 are melted by heat in this way, the solder moves to the pad main body 135 having a larger area by wetting of solder.

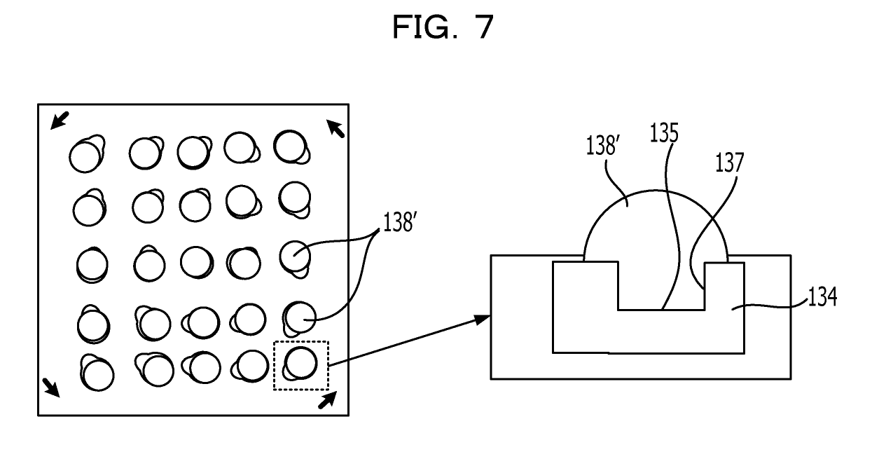

FIG. 7 illustrates a state after the solder wets and moves.

In the same manner as in FIGS. 4 and 6, in FIG. 7, the area where the above-described electrode pads 134 are arranged on the wiring board 131 is shown, and on the right side of the figure, an enlarged view of a cross-sectional structure focused on a single electrode pad 134 is shown.

Solder 138′, which is the heat-melted solder of the solder bump 138 and the solder printing 139, wets and moves to a larger area and flows into the depression 137, so that the solder 138′ is strongly attracted to the pad main body 135. Finally, the soldering is performed in a state where the center of the pad main body 135 and the center of the solder 138′ almost match each other. As a result, when seeing the solders 138′ as a whole, a rotational movement is generated in the direction indicated by arrows in FIG. 7.

Although the movement of the solder caused by wetting is generated only when the solder before melting is shifted and placed on a circular pad, in this embodiment, the protruding portion 136 and the depression 137 are provided, so that the movement of the solder 138′ is reliably generated.

When the solder 138′ wets and moves in this way, self-alignment of the electronic component 132 occurs along with the movement.

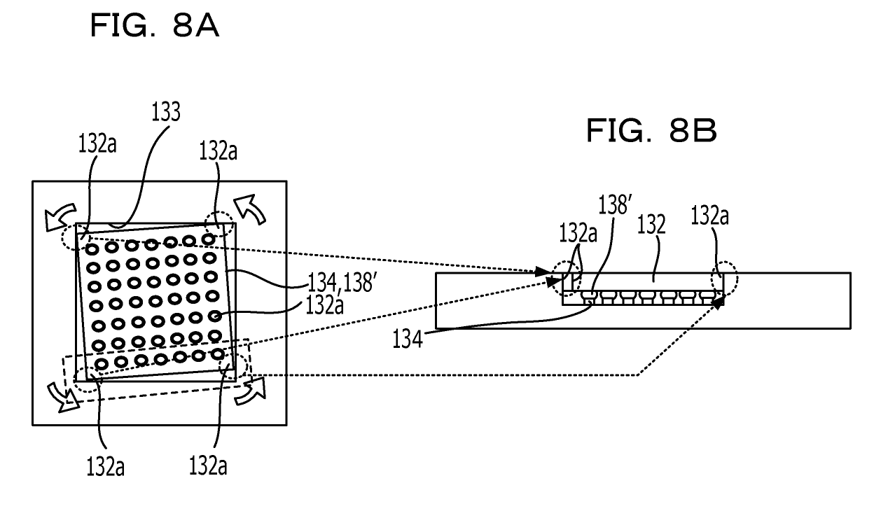

FIG. 8 illustrates the self-alignment of the electronic component according to the first embodiment.

FIG. 8A illustrates a top view and FIG. 8B illustrates a side perspective view.

As described above, the solder 138′ wets and moves. As a result, the position of the solder 138′ almost matches the position of the electrode pad 134. When the solder wets and moves in this way, the electronic component 132 also rotates in the direction indicated by arrows in FIG. 8 by the self-alignment. The rotated electronic component 132 is thus in a state where the four corners 132a are in contact with the opening 133. When the corners 132a are in contact with the opening 133 in this way, as described below, stress concentration on the joints between the solder 138′ and the electrode pad 134 can be avoided.

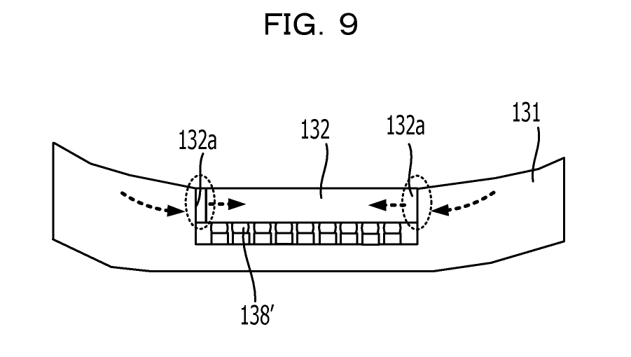

FIG. 9 illustrates that stresses on the solder joints are alleviated.

Deformation may occur in the wiring board 131 because of an external force, temperature change, and the like applied to the thin personal computer 100. When the deformation as shown in FIG. 9 occurs in the wiring board 131, stresses as shown by arrows in FIG. 9 are generated by the deformation. In this embodiment, such stresses are transmitted to the corners 132a of the electronic component 132, so that the stresses are received by the package itself of the electronic component 132. Therefore, a case in which the stresses concentrate on the solder 138′ is avoided, so that the solder 138′ is not detached.

In the first embodiment, outer circumferential pads in the grid pattern include a protruding portion in a width direction to form a spiral-shaped trajectory with respect to a centered pad in the grid pattern.

According to this feature, the solder reliably wets and moves from the protruding portion to the main body by the deviation of the shape of the pad. As a result, a spiral movement of the solder occurs reliably in the plurality of pads as a whole. Therefore, the electronic component reliably rotates by the self-alignment by normally placing the electronic component on the pads and performing soldering. By the rotation, a state can be reliably obtained in which the corner portions of the electronic component are in contact with inner edges of the opening or the wall.

In the first embodiment, outer circumferential pads in the grid pattern include a depression provided in the thickness direction of the printed wiring board.

According to this feature, the solder reliably wets and moves to the depression. As a result, the corner portions of the electronic component are in contact with inner edges of the opening or the wall.

Although a circular depression is employed because of ease of work or the like in the first embodiment, the shape of the depression is not limited to a circular shape, but it can also be an elliptical shape, a polygonal shape, a groove shape, etc.

Hereinafter, a second embodiment will be described. Please note that the same or similar elements as those of the first embodiment are given the same reference numerals and redundant description will be omitted.

In the second embodiment, the shape of the electronic component is different from that of the first embodiment.

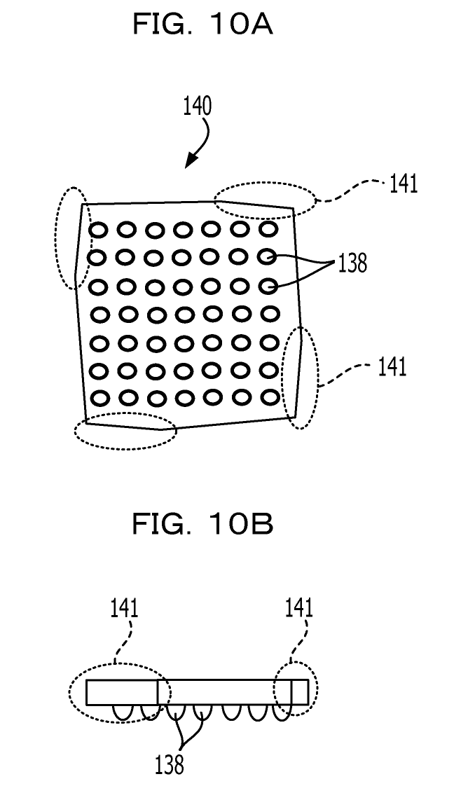

FIGS. 10A and 10B illustrate the electronic component according to the second embodiment.

FIG. 10A illustrates a top view and FIG. 10B illustrates a side view.

The electronic component 140 according to the second embodiment has an octagonal outer shape as a whole, and portions that come into contact with the opening 133 are provided as flat portions 141. The arrangement of the solder bumps 138 with respect to the electronic component 140 can be similar to that of the first embodiment.

When the electronic component 140 is mounted on the wiring board 131, in the same manner as in the first embodiment, the electronic component 140 is placed in an area surrounded by the opening 133.

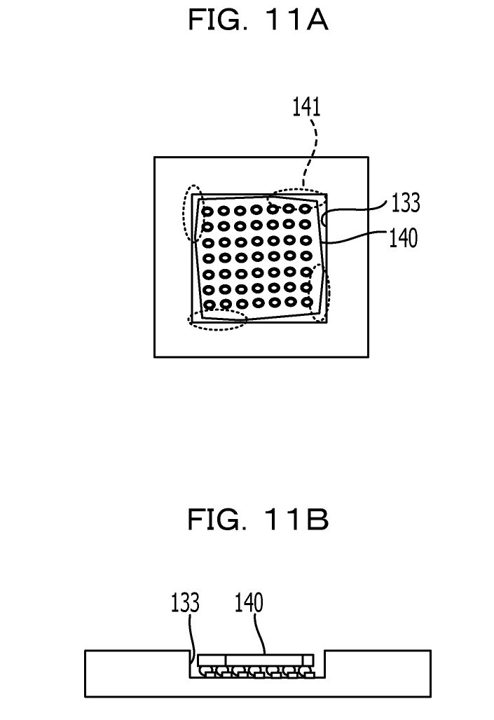

FIG. 11 illustrates a state in which the electronic component according to the second embodiment is placed in the opening of the wiring board.

FIG. 11A illustrates a top view and FIG. 11B illustrates a side perspective view.

The electronic component 140 is placed in the area surrounded by the opening 133 in a state in which the opening 133 and the flat portions 141 are detached from each other. When the solder is melted by heat, a self-alignment similar to that in the first embodiment occurs.

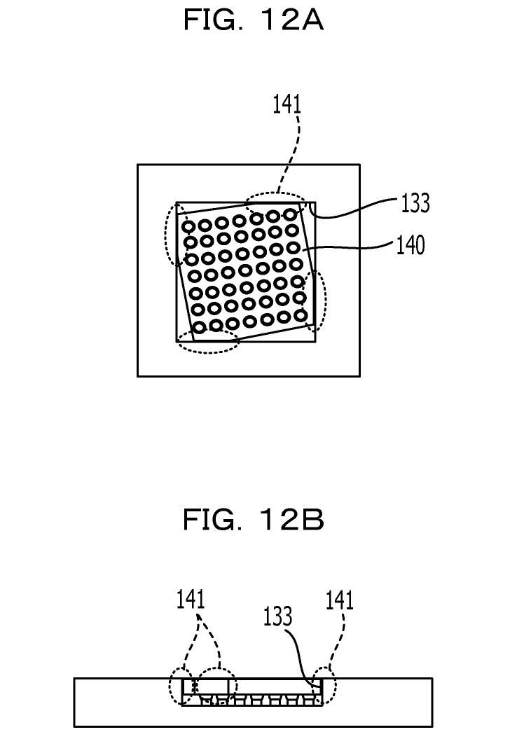

FIG. 12 illustrates the self-alignment of the electronic component according to the second embodiment.

FIG. 12A illustrates a top view and FIG. 12B illustrates a side perspective view.

In the second embodiment, as a result of the self-alignment of the electronic component 140, the flat portions 141 are in flat contact with the opening 133. When the flat portions 141 are in flat contact with the opening 133 in this way, the contact area increases. As a result, the stress received from the opening 133 is dispersed to the entire electronic component 140, so that the stress concentration on the solder joints can be more reliably avoided.

In the second embodiment, at least one of outer edges of the electronic component is in surface contact with an inner edge of either one of the opening or the wall.

Next, a third embodiment will be described. In the third embodiment, the shape of the electronic component is different from that of the first embodiment.

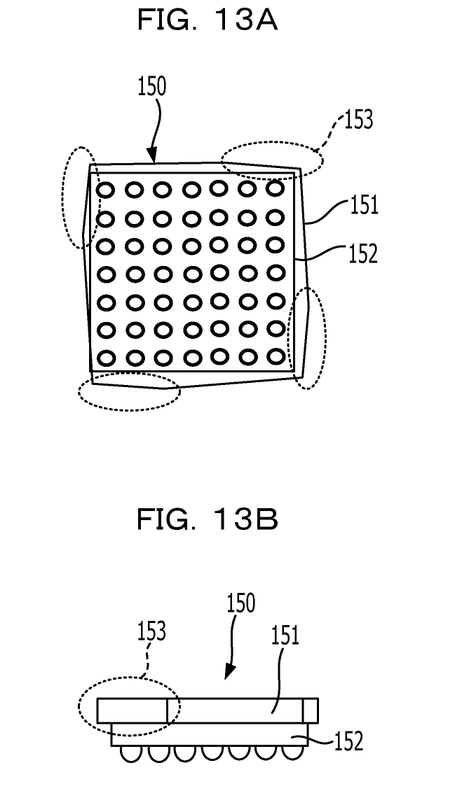

FIG. 13 illustrates the electronic component according to the third embodiment.

FIG. 13A illustrates a top view and FIG. 13B illustrates a side view.

The electronic component 150 shown in FIG. 13 includes a package section 152 in which an electronic circuit is enclosed and a plate member 151 additionally attached to the surface of the package section 152. The package section 152 has a rectangular shape. On the other hand, the plate member 151 has an octagonal shape as a whole in the same manner as the electronic component 140 in the second embodiment, and portions that are in contact with the opening 133 in the plate member 151 are provided as flat portions 153. When the electronic component 150 is mounted on the wiring board 131, the electronic component 150 is also placed in an area surrounded by the opening 133. An example of the placement of the electronic component 150 will be described below.

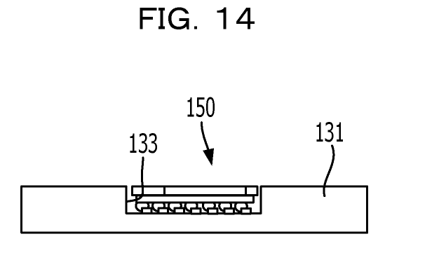

FIG. 14 illustrates the example of the placement of the electronic component according to the third embodiment.

As the example of the placement of the electronic component, in the same manner as in the first embodiment and the second embodiment, the electronic component 150 is placed in an area surrounded by the opening 133 of the wiring board 131.

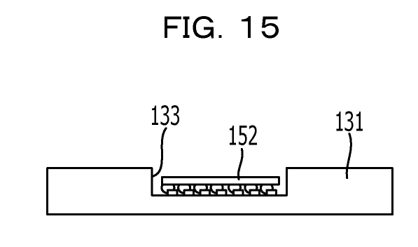

FIG. 15 illustrates a modified example of the placement of the electronic component according to the third embodiment.

As the modified example of the placement of the electronic component, in an area surrounded by the opening 133 of the wiring board 131, first, only the package 152 of the electronic component 150 is placed in the opening 133. Thereafter, the plate member 151 is attached to the upper surface of the package 152, so that the same state as that shown in FIG. 14 appears.

After the electronic component 150 is placed, when the solder is melted by heat, a self-alignment similar to those in the first embodiment and the second embodiment occurs.

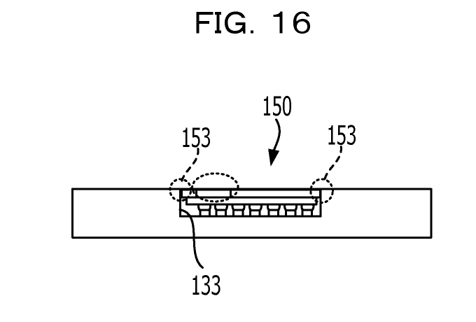

FIG. 16 is a side perspective view illustrating a result of the self-alignment according to the third embodiment.

In the same manner as in the second embodiment, also in the third embodiment, as a result of the self-alignment of the electronic component 150, the flat portions 153 are in flat contact with the opening 133. Therefore, the contact areas are large, and thus the stress received from the opening 133 is dispersed to the entire package of the electronic component 150. As a result, avoidance of the stress concentration on the solder joints is more reliable. In the case of the third embodiment, the stress is mainly applied to the plate member 151 of the electronic component 150, so that the load of the package 152 is also alleviated. In the third embodiment, the electronic component can include a package portion and a plate member. The package portion encloses semiconductor devices such as ICs and LSIs therein. The plate member is a polygonal member attached to the package portion, and at least one side of the outer edges thereof is in surface contact with an inner edge of at least either one of the opening or the wall.

Next, a fourth embodiment will be described. In the fourth embodiment, the shape of the inner edges of the opening is different from that of the first embodiment.

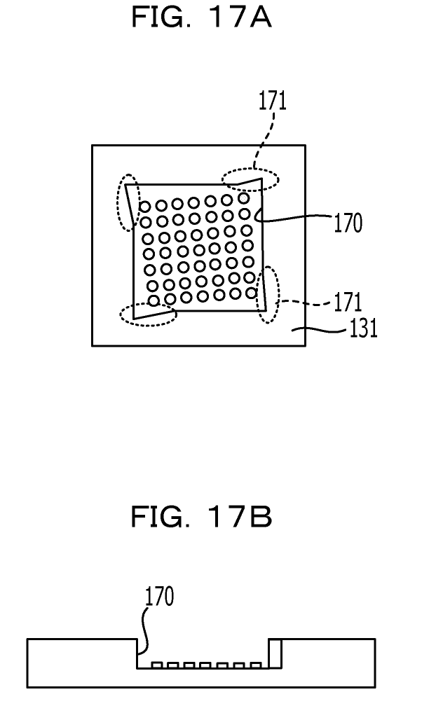

FIG. 17 illustrates the shape of a wall according to the fourth embodiment.

FIG. 17A illustrates a top view and FIG. 17B illustrates a side perspective view.

In the fourth embodiment, there is an opening 170, the shape of which is different from the shape of the opening 133 which surrounds the rectangular area in the first embodiment, and in which portions that come into contact with the electronic component 132 when the self-alignment of the electronic component 132 is performed are provided and protrude to outside.

In the same manner as in the first embodiment, the electronic component 132 is placed in an area surrounded by the opening 170.

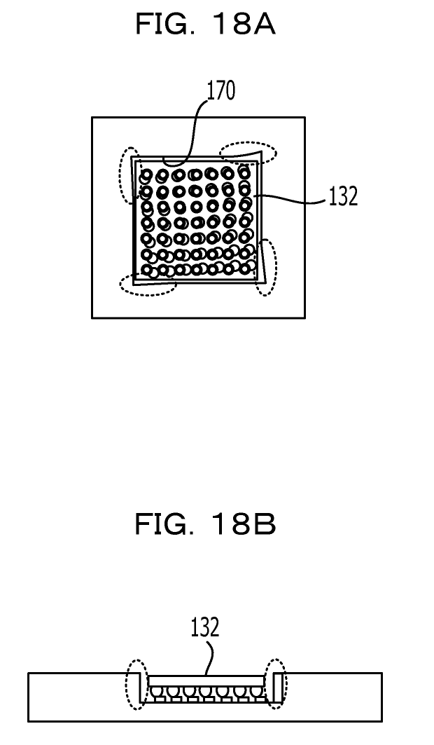

FIG. 18 illustrates a state in which the electronic component is placed in the fourth embodiment.

FIG. 18A illustrates a top view and FIG. 18B illustrates a side perspective view.

As shown in FIGS. 18A and 18B, also in the fourth embodiment, the electronic component 132 is placed while the electronic component 132 is not in contact with the opening 170. When the solder is melted by heat, a self-alignment similar to that in the first embodiment occurs.

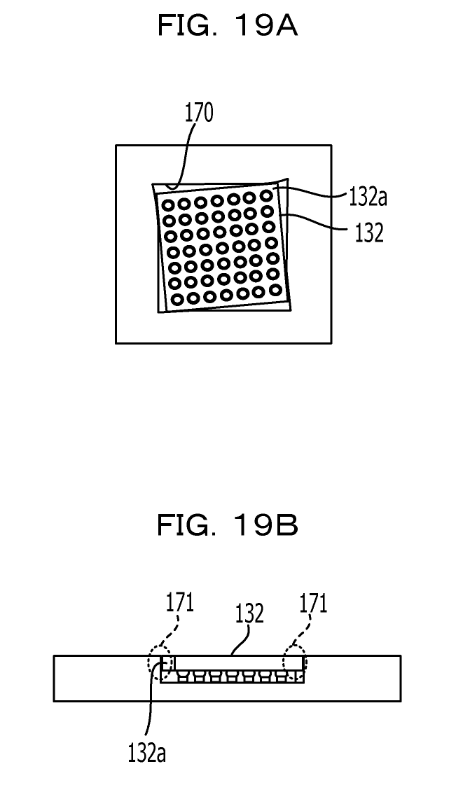

FIG. 19 illustrates a result of the self-alignment according to the fourth embodiment.

FIG. 19A illustrates a top view and FIG. 19B illustrates a side perspective view.

In the fourth embodiment, as a result of the rotation of the self-alignment of the electronic component 132, portions of the corners 132a of the electronic component 132 are received in a wide and flat area on concave portions 171 of the opening 170. When the portions of the corners 132a are received in a wide and flat area on the concave portions 171 in this way, in the same manner as in the first embodiment and the second embodiment, the stress from the opening 170 is dispersed to the entire package of the electronic component 132. In the fourth embodiment, at least one side of inner edges of either one of the opening or the wall includes an extension portion having a different degree of tilt with respect to an outer edge of the arrangement of the plurality of pads.

Next, a fifth embodiment will be described. In the fifth embodiment, a wall is provided instead of the opening as compared to that of the first embodiment.

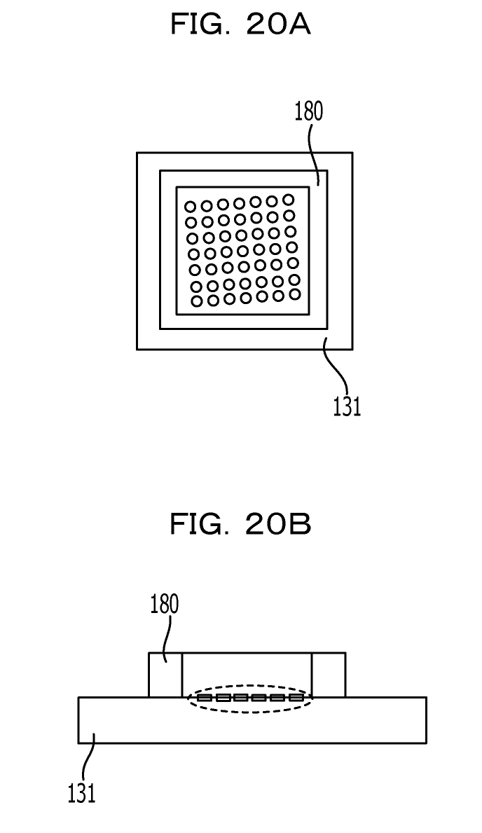

FIG. 20 illustrates the structure of the wall according to the fifth embodiment.

FIG. 20A illustrates a top view and FIG. 20B illustrates a side perspective view.

In the fifth embodiment, a wall 180 is provided to project from the surface of the wiring board 131. Such a wall 180 is suitable for a case in which the thickness of the wiring board 131 is small and it is not easy to provide an opening recessed from the surface as in the first to the fourth embodiments. The electronic component 132 is placed in an area surrounded by the wall 180.

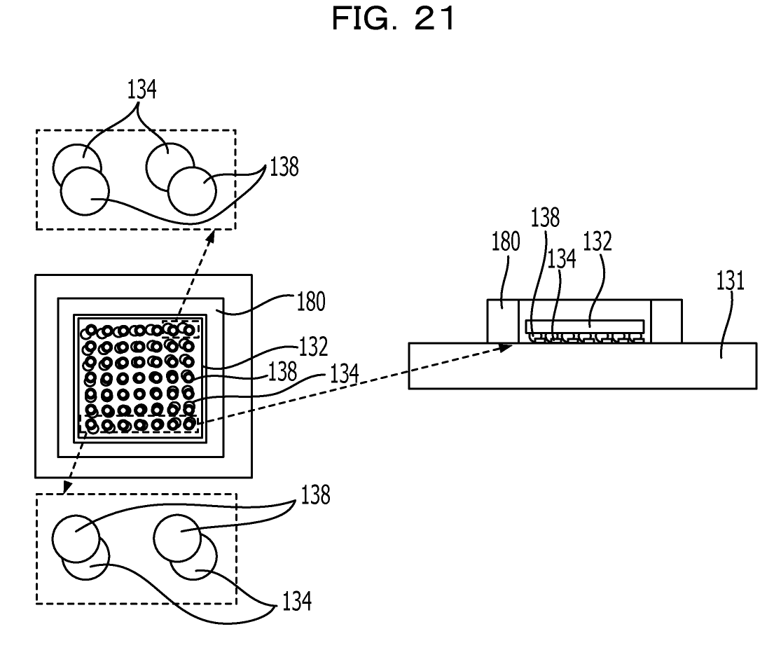

FIG. 21 illustrates the placement of the electronic component according to the fifth embodiment.

FIG. 21A illustrates a top view and partially enlarged views and FIG. 21B illustrates a side perspective view.

In the fifth embodiment, the electronic component 132 is placed in a surface area of the wiring board 131 surrounded by the wall 180 projecting from the surface of the wiring board 131. At this time, the positional relationship between the electrode pads 134 and the solder bumps 138 is similar to that in the first embodiment. After the electronic component 132 is placed in this way, the solder bumps 138 are heated along with the wiring board 131, and the solder bumps 138 are melted. When the solder bumps 138 are melted, a self-alignment occurs in the same manner as in the first embodiment.

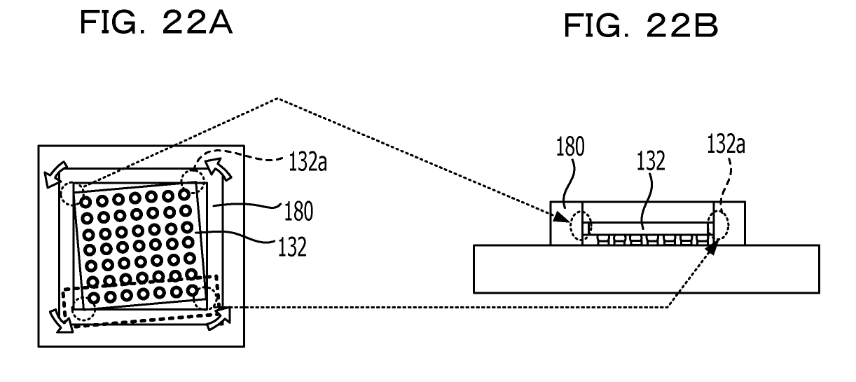

FIG. 22 illustrates a result of the self-alignment according to the fifth embodiment.

FIG. 22A illustrates a top view and FIG. 22B illustrates a side perspective view.

Also in the fifth embodiment, the electronic component 132 rotates by the self-alignment in the direction indicated by arrows shown in FIG. 22A. As a result of the rotation, portions of the corners 132a of the electronic component 132 come into contact with the inner surface of the wall 180. Also, when the portions of the corners 132a of the electronic component 132 are in contact with the inner surface of the wall 180 projecting from the surface of the wiring board 131, a case in which the stress accompanying the deformation of the wiring board 131 concentrates on a soldered portion is avoided.

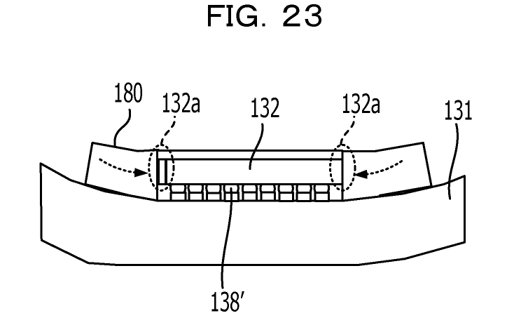

FIG. 23 illustrates that the stress concentration on the solder joints is avoided also in the fifth embodiment.

When the deformation as shown in FIG. 23 occurs in the wiring board 131 in the fifth embodiment, stresses as shown by arrows in FIG. 23 are applied to the wall 180. The stresses are transferred from the wall 180 to the portions of the corners 132a of the electronic component 132. Then, the stresses transferred to the portions of the corners 132a are received by the package itself of the electronic component 132. Therefore, also in the fifth embodiment, a case in which the stresses concentrate on the solder 138′ is avoided, so that the solder 138′ is not detached.

In the fifth embodiment, the shape of the inner surface of the wall 180 and the shape of the electronic component 132 are similar to those in the first embodiment. However, even when the wall is used instead of the opening, the same shapes of the electronic component as those in the second embodiment and the third embodiment can be used. Also, even when the wall is used, the same shape of inner edge as that the fourth embodiment can be used.

Although, in the first to the fifth embodiments described above, a typical rectangular shape is mainly described as the shape of the electronic component, as the shape of the electronic component of the above-described embodiment, a triangular shape, a pentagonal shape, a hexagonal shape, an octagonal shape, and so forth may be used in addition to the rectangular shape.

In the first to the fifth embodiments, soldering of the BGA method is described as a specific example of soldering, as soldering for fixing the electronic component of the above-described embodiment on the board main body, the flip-chip method may also be employed.

All examples and conditional language recited herein are intended for pedagogical objects to aid the reader in understanding the invention and the concepts contributed by the inventors to further the art, and are to be construed as being without limitation to such specifically recited examples and conditions, nor does the organization of such examples in the specification relate to a showing of the superiority and inferiority of the invention. Although the embodiments of the invention have been described in detail, it will be understood by those of ordinary skill in the relevant art that various changes, substitutions, and alterations could be made hereto without departing from the spirit and scope of the invention as set forth in the claims.

We claim:

1. A printed wiring board for mounting an electronic component thereon, said printed wiring board comprising:
a surface;
an opening recessed from the surface, the opening having a dimension corresponding to a dimension of an electronic component configured to be housed therein; and
a plurality of pads disposed on a bottom surface of the opening, the plurality of pads having a skew arrangement in a grid pattern with respect to inner edges of the opening.

2. The printed wiring board according to claim 1, further comprising outer circumferential pads in the grid pattern, said outer circumferential pads including a protruding portion in a width direction to form a spiral-shaped trajectory with respect to a centered pad in the grid pattern.

3. The printed wiring board according to claim 1, further comprising outer circumferential pads in the grid pattern, said outer circumferential pads including a depression provided in a thickness direction of the printed wiring board.

4. The printed wiring board according to claim 1, wherein at least one of inner edges of the opening includes an extension portion having a different degree of tilt with respect to an outer edge of the arrangement of the plurality of pads.

5. A printed wiring board for mounting an electronic component thereon, said printed wiring board comprising:
a wall projecting from a surface of the printed wiring board, the wall having a dimension corresponding to a dimension of an electronic component configured to be housed therein; and
a plurality of pads disposed on a region surrounded by the wall, the plurality of pads having a skew arrangement in a grid pattern with respect to inner edges of the wall.

6. The printed wiring board according to claim 5, further comprising outer circumferential pads in the grid pattern, said outer circumferential pads including a protruding portion in a width direction to form a spiral-shaped trajectory with respect to a centered pad in the grid pattern.

7. The printed wiring board according to claim 5, further comprising outer circumferential pads in the grid pattern, said outer circumferential pads including a depression provided in the thickness direction of the printed wiring board.

8. The printed wiring board according to claim 5, wherein at least one of inner edges of the opening includes an extension portion having a different degree of tilt with respect to an outer edge of the arrangement of the plurality of pads.

9. An electronic apparatus comprising:
a semiconductor package;
a printed wiring board supporting an electronic component thereon, said printed wiring board including a surface;
an opening recessed from the surface of the printed wiring board, the semiconductor package housed in the opening; and
an enclosure enclosing the printed wiring board,
wherein the semiconductor package is housed in the opening such that a periphery of the semiconductor package is tilted with respect to an inner edge of the opening.

10. The printed wiring board according to claim 9, wherein at least one side of the semiconductor package is in contact with the inner edge of the opening.

11. An electronic apparatus, comprising:
a semiconductor package;
a printed wiring board supporting an electronic component thereon, said printed wiring board including a surface;
a wall projecting from the surface of the printed wiring board, the semiconductor package housed in a recess defined by the wall; and
an enclosure enclosing the printed wiring board,
wherein the semiconductor package is housed in the wall such that a periphery of the semiconductor package is tilted with respect to an inner edge of the wall.

12. The electronic apparatus according to claim 11, wherein at least one side of the semiconductor package is contact with the inner edge of the wall.
